(19) United States
(12) Patent Application Publication
(10) Pub. No.: US 2018/0142346 A1
(43) Pub. Date: May 24, 2018

(54) PROCESS FOR DOPING GRAPHENE

(71) Applicant: COMMISSARIAT A L'ENERGIE ATOMIQUE ET AUX ENERGIES ALTERNATIVES, Paris (FR)

(72) Inventors: Hélène LE POCHE, GRENOBLE (FR); Alexandre CARELLA, MAZERES-LEZONS (FR); Jean DIJON, GRENOBLE (FR); Hanako OKUNO, GRENOBLE (FR); Emilie RAUX, GRENOBLE (FR)

(21) Appl. No.: 15/819,467

(22) Filed: Nov. 21, 2017

(30) Foreign Application Priority Data
Nov. 22, 2016 (FR) 1661352

(51) Int. Cl. C23C 16/26; H01B 1/04; H01B 5/14; H01B 13/00

(52) U.S. Cl. CPC C23C 16/26; H01B 13/0036; H01B 5/14; H01B 1/04

(57) ABSTRACT

The present application relates to a process that is useful for preparing a graphene layer that is transparent and of stabilized and improved electrical conductivity, the process comprising at least the steps of:

(i) providing at least one graphene layer that is transparent and that possesses a sheet resistance, R□ini,
(ii) doping at least one zone of the graphene layer to form a doped graphene zone having a stabilized sheet resistance, R□∞, of value lower than R□ini,
wherein step (ii) is carried out by spraying the surface of at least the zone of the graphene layer (i) with at least one dopant chosen from organometallic complexes and salts of platinum or palladium of +IV or +II oxidation state.

The present invention relates to a process that is useful for increasing, by chemical doping, the electrical conductivity of transparent graphene while preserving therefor a satisfactory transparency. The graphene thus doped proves to be most particularly advantageous for forming transparent conductive electrodes for display devices or solar cells.

Currently, the transparent conductive materials favored for these uses are transparent conductive oxides (TCOs) and more particularly tin-doped indium oxide (ITO). However, the use of these materials has a certain number of drawbacks, in particular with regard to the high and fluctuating cost of indium and to the high mechanical fragility of ITO, which is incompatible with applications on flexible substrates.

Now, graphene, which combines a good electrical conductivity and a high transparency, is precisely very advantageous in these two regards cost and flexibility. It may therefore be a very advantageous alternative to ITO provided that its electrical conductivity can be maximized while preserving a sufficiently high optical transmittance.

More precisely, monolayer graphene is a transparent material with a low optical absorbance in the visible of about 2.3%. Its electrical conductivity (σ) is correlated with the charge carrier density (n) and with the mobility of these carriers (μ) by the relationship σ=e×n×μ (e: elementary charge). Therefore, to be an advantageous alternative to the other transparent conductive oxides such as ITO, this improved conductivity would need to be correlated with a low sheet resistance (R□) while remaining paired with a transmittance over all of the visible spectrum higher than or equal to 85%.

It is known that the choice of a graphene monolayer of high crystalline quality (high mobility), typically graphene produced by chemical vapor deposition (CVD) is key to obtaining a satisfactory electrical performance paired with a satisfactory optical performance. A few graphene monolayers may also be stacked in limited number in order to preserve a good transparency.

Nevertheless, the best graphene monolayers have a sheet resistance of several hundred ohms/square. It therefore remains necessary to consider doping this graphene monolayer in order to decrease its electrical resistance and therefore increase its electrical conductivity.

Among the various existing doping techniques, chemical doping ex-situ (post-production of the graphene) by charge transfer leads to the best electrical performance because the crystal structure of the graphene (sp2 hybridization) is not modified by the doping. The electrical conductivity of the graphene may thus be improved by increasing charge carrier density.

Dopants of a plurality of chemical natures have already been considered for graphene. Thus, the p-type dopants the most commonly used and among the most effective correspond to acids, such as for example HNO₃ and HCl, as described in the publication Bae et al., Nature Nanotechnology 5, 2010, 574, and the patent application US 2015/0162408 A1, and/or to oxidants such as metal salts based for example on Au (AuCl₃, HAuCl₄, etc.) as described in the publications Kim et al., Nanotechnology, 21, 2010, 285205, Kobayashi et al., Appl. Phys. Lett., 102, 2013, 023112, and Bae et al., Nature Nanotechnology, 5, 2010, 574, or Fe (FeCl₃, etc.) as described in the publication Khrapach et al., Adv. Mater., 24 2012, 2844. For their part, documents WO 2014/065534 A1 and CN 102180463 mention the possible use of salts or complexes based on Pt (HPtCl₄, H₂PtCl₆) or Pd (H₂PdCl₆, Pd(OAc)₂) without giving electrical performance metrics in terms of doping efficacy.

In the large majority of cases, these dopants are implemented, in dispersion or solubilized, in liquid solutions that are deposited on the surface of the graphene by submergence or dipping as described in patent application US 2015/0162408 A1 or optionally by spin-coating in which the doping solution is spread over the surface of rotating graphene as described in the publication Kim et al., Nanotechnology, 21, 2010, 285205. Patent applications WO 2014/065534 A1 and CN 104528698 make reference to a deposition of the doping solution on the surface of the graphene by “dropping”, i.e. deposition of the solution locally drop by drop. As regards patent applications CN 104528698 and CN 104607344, they describe a deposition of the doping solution by spraying, which consists in nebulizing the liquid solution conveying the dopant agent into a mist of fine droplets above the sample.

Unfortunately, these doping techniques prove not to be completely satisfactory for the following reasons.

Firstly, the requirement of uniformity of the doped graphene over large areas is most often not satisfied with these deposition techniques and most particularly with spin-coating or “dropping”.

Furthermore, the obtainment simultaneously of a good electrical performance paired with a satisfactory optical performance remains, in the large majority of cases, non-competitive with respect to ITO. The achievement of this requirement clearly requires the quantity of dopants which is deposited on the surface of the graphene to be controllable. However, it is difficult to adjust this quantity. Specifically, conventionally, it is sought to minimize this quantity of dopants, on the one hand, in order not to too greatly degrade optical transparency and, on the other hand, to preserve a good doping efficacy. Specifically, an excess of dopants is considered as being of a nature to degrade the electrical conductivity by excessively decreasing mobility.

Lastly, the main problem of chemical doping resides in the instability of the dopants. For most of the doping techniques, doping efficacy is not maintained during temporal ageing of the samples under ambient conditions (air, humidity) or during a heat treatment (typically for T≥100° C.), making the doping incompatible with technologies for manufacturing transparent electrodes.

Regarding the latter aspect, it has been proposed to stabilize the dopants by encapsulating them using a graphene layer that is superposed on the doped graphene layer as described in patent applications US 2015/0162408 and CN 10 4528 698. In fact, in the majority of cases, this type of stack is not producible using conventional techniques for transferring graphene by wet processing via a sacrificial polymer carrier as described in the publication Suk et al., ACS Nano, 5, 2011, 6916. Specifically, the dopants deposited on the lower graphene layer are removed during the transfer of the upper graphene layer. Another proposed alternative consists in stabilizing the dopants by adding a hydrophobic organic layer to the surface of the doped graphene such as described in patent application WO 2014/065534 A1. Unfortunately, there then arises the problem of the decrease of the optical transmittance of the stack and of the way of forming this upper layer without removing the dopants.

Therefore, at the present time there exists, to the knowledge of the inventors, no method for doping a graphene layer that allows graphene to be achieved that is uniformly doped, that remains endowed with a good transparency and the doping of which is effective and stabilized.

The object of the present invention is precisely to provide a new doping method meeting all of these requirements.

In particular, the present invention aims to provide a process that is useful for accessing effective and stabilized chemical doping of a transparent graphene layer while preserving for this layer a transmittance of at least 85%.

It furthermore aims to provide a new doping technique that is compatible with an implementation, in particular with roll-to-roll on-the-fly methods, on large-scale carbon layers carried on flexible substrates.

More precisely, according to a first aspect, the present invention relates to a process that is useful for preparing a graphene layer that is transparent and of stabilized and improved electrical conductivity, said process comprising at least the steps consisting in:
(i) providing at least one graphene layer that is transparent and that possesses a sheet resistance, R□ini and
(ii) doping at least one zone of said graphene layer to form a doped graphene zone having a stabilized sheet resistance, R□∞, of value lower than R□ini,
   characterized in that step (ii) is carried out by spraying the surface of at least said zone of said graphene layer (i) with at least one dopant chosen from organometallic complexes and salts of platinum or palladium of +IV or +II oxidation state.

Advantageously, the quantity of dopant Q_{D} is adjusted to form a doped graphene zone that is endowed with the expected minimized and stabilized sheet resistance, R□∞.

According to one preferred variant, the doped graphene zone furthermore possesses a transmittance value higher than 85% over all of the visible spectrum.

In the context of the invention, a stabilized sheet resistance, or even R□∞, is understood to mean a sheet resistance the value of which does not increase significantly, in particular by more than 8% of its value during temporal ageing of the doped graphene layer, under ambient conditions (air, moisture).

Specifically, completely unexpectedly, the inventors have observed that provided that the choice is made of particular dopants, of an adjustment of their quantity in the doping and of a doping mode according to the invention, it proves to be possible to access doped graphene layers that are endowed with a significant conductivity improvement that is stabilized over time.

It will be recalled that sheet resistance may be defined by the following formula:

$$R □ = \frac{ρ}{e} = \frac{1}{σ \cdot e}$$

in which:
e is the thickness of the conductive film (in cm);
σ is the conductivity of the film (in S/cm) (σ=1/ρ); and
ρ is the resistivity of the film (in Ω·cm).

It will also be recalled that the doping of a graphene layer has the immediate effect of decreasing the sheet resistance R□ini, of this layer to a value R□D.

However, as mentioned in the preamble of the present text, it is generally not possible to preserve this value R□D, measured just after deposition. It significantly increases during temporal ageing of the doped graphene layer and this results in a gradual loss of doping efficacy.

The process according to the invention precisely allows doping efficacy to be preserved over time.

The stabilized sheet resistance, R□∞ obtained using the process according to the invention, therefore quantifies an R□ value that is stable over time.

Thus, the process of the invention advantageously allows a conductivity improvement to be guaranteed in the zone of doped graphene throughout its ageing.

This efficacy improvement is in particular obtained according to the invention by virtue of the implementation of a quantity in excess of dopants.

In the context of the invention, the expression “quantity in excess of dopant” is understood to make reference to quantities of dopant higher than or equal to the minimum required quantity of dopants above which the value of R□D no longer varies or no longer decreases or even does not decrease by more than 8% of its value, when dopants are added to the surface of the graphene (FIG. 2a).

In contrast, the higher the quantity of dopants, the higher the doping efficacy after stabilization or the lower R□∞.

Furthermore, according to one preferred embodiment of the invention, this quantity in excess of dopants present within the zone of doped graphene, which is suitable for giving, to said zone of doped graphene a minimized sheet resistance R□∞ is furthermore suitable for allowing the zone of doped graphene, to manifest a transparency and in particular a transmittance of at least 85% over all of the visible spectrum.

Advantageously, the graphene layer of step (i) of the process is carried by a substrate.

Preferably, the substrate is transparent or translucent in the visible or infrared domain and preferably chosen from glass, polyethylene terephthalate (PET), polycarbonate (PC), polyimide (PI), polyethylene naphthalate (PEN), polydimethylsiloxane (PDMS), polystyrene (PS), polyethersulfone (PES), silicon covered with a layer of oxide such as SiOₓ, Al₂Oₓ, or a nitride layer, and preferably chosen from glass and polyethylene terephthalate. The graphene layer of step (i) is in particular a graphene monolayer produced by a chemical-vapor-deposition (CVD) technique.

According to one variant embodiment, the graphene layer of step (i) makes direct contact with the substrate.

According to another variant embodiment, the graphene layer makes contact with a layer of doped graphene of transmittance in the visible domain at least equal to 90%, which is inserted between said substrate and said graphene layer to be doped.

According to yet another variant embodiment, the graphene layer makes contact with a layer of undoped graphene, which layer is advantageously transparent and in particular of transmittance in the visible domain at least equal to 97%, and which layer is inserted between said substrate and said graphene layer to be doped.

Advantageously, the dopant is chosen from:
salts of platinum or palladium of formulae:

A₂MX₆,MX₄,A₂MX₄ and MX₂

in which:
A is a hydrogen atom, an NH₄ group, a sodium atom, a lithium atom or a potassium atom;
X is a fluorine atom, a chlorine atom, a bromine atom or an iodine atom; and
M is a platinum atom or a palladium atom of +IV or +II oxidation state.

Preferably, the dopant is chosen from the salts of PtCl₄, H₂PtCl₆, H₂PtC₄, PtCl₂, H₂PdCl₆, PdCl₂, K₂PdCl₄, etc. and mixtures thereof. According to one preferred embodiment, the one or more dopants in question according to the invention are implemented within a liquid solution.

According to one preferred embodiment, the liquid solution of dopant(s) is sprayed by way of a stationary nozzle or a movable nozzle.

Preferably, the liquid solution of dopant(s) is sprayed automatically by means of a nozzle subjected to ultrasonic vibrations.

In particular, the operation of spraying onto the graphene layer may be carried out in one go or repeated one or more times.

According to one particular embodiment, a stencil mask may be inserted between the nozzle and the graphene layer to be doped in order to define a doping zone.

According to one preferred variant embodiment, step (ii) of the process according to the invention is carried out in dynamic mode using an on-the-fly doping technique and in particular a roll-to-roll technique.

Advantageously, the substrate carrying the graphene layer treated in step (ii) is heated to a temperature propitious to the removal of the solvent medium of the liquid solution of dopant.

Advantageously, the process according to the invention furthermore comprises the additional steps consisting in:

(ia) obtaining the value of the transmittance Tᵢₙᵢ of the graphene layer in question in step (i) preliminarily to the performance of step (ii);

(iia) measuring the value of the transmittance T_{D} of said doped graphene layer just after the doping step (ii); and

(iib) evaluating the quantity of dopants by comparing the transmittance T_{D} to the transmittance Tᵢₙᵢ, a value T_{D} lower than a value Tᵢₙᵢ being representative of effective doping.

The transmittance measurements may be carried out by an on-line measurement by means of a visible or near-infrared laser.

Advantageously, the process according to the invention furthermore comprises, consecutively to the doping step (ii), and if present step (iib), a step (iii) of stabilizing the concentration of organometallic complexes or salts of platinum or palladium of +IV or +II oxidation state in the doped graphene layer.

According to one variant embodiment, step (iii) consists in a temporal stabilization operation. If required, this stabilization may be accelerated by thermal processing. The implementation of such a step is clearly within the ability of a person skilled in the art.

Advantageously, the process according to the invention comprises, furthermore, consecutively to the doping step (ii), and if present stabilization step (iii) such as defined above, at least one step (iv) consisting in transferring, by dry processing or by wet processing, a graphene layer possessing a transmittance at least equal to 97% in particular in the visible domain, to the surface of the layer of doped graphene which is obtained at the end of step (ii).

Preferably, the process comprises consecutively to step (iii) or (iv) a measurement of the value of the transmittance T_{∞} of said layer of doped and stabilized graphene.

According to one variant embodiment of the invention, the dopant is PtCl₄, and the corresponding layer of doped and stabilized graphene possesses, a stabilized sheet resistance, R□∞ lower than or equal to 350Ω/□, and preferably lower than or equal to 300Ω/□, or even lower than or equal to 200Ω/□ and advantageously a transmittance T higher than 85% over all of the visible spectrum.

According to another aspect, the present invention relates to a material comprising at least one layer of doped graphene obtained by the process such as defined according to the invention.

According to yet another aspect, the present invention relates to the use of a layer of doped graphene obtained by the process such as defined according to the invention to manufacture flexible and ultra-thin screens, touchscreens, batteries, solar cells, biosensors, electronic devices or optoelectronic devices in the visible or infrared domain, spintronics devices, transparent conductive electrodes intended to be incorporated into viewing devices such as displays, display screens, flat screens, and organic light-emitting diodes (OLED) or into photovoltaic devices.

According to yet another aspect, the present invention relates to a device, in particular such as listed above, comprising doped graphene obtained by the process such as defined according to the invention or a material such as defined according to the invention.

### I—Doping Process According to the Invention

As will be clear from the above, the process allows the electrical conductivity of a transparent graphene layer to be increased significantly and in a stabilized way while allowing said layer to preserve advantageous transmittance properties.

To do this, this process implements a chemical charge-transfer doping technique involving, on the one hand, the choice of a particular doping agent, on the other hand, the choice of a specific doping mode, and lastly the adjustment of a specific concentration of dopants in the layer of doped graphene.

### a) Graphene Layer to be Doped

As specified above, this graphene layer is transparent.

In the context of the invention, the expression transparence or transmittance is not limited to the visible domain. It may also characterize a transparency in the infrared domain.

However, according to one preferred variant, this transparency characterizes a transparency in all of the visible domain.

More precisely, the graphene layer to be doped according to the invention possesses a transmittance in all of the visible spectrum at least equal to 85%.

Preferably, the graphene layer to be doped possesses a transmittance value higher than or equal to 90% and preferably higher than 95% over all of the visible spectrum.

It is recalled that the transmittance of a given structure represents the light intensity passing through the structure in the visible spectrum.

It may be measured by UV-visible spectrophotometry, for example using an integrating sphere on a Varian Carry spectrophotometer.

The transmittance in the visible spectrum corresponds to the transmittance for wavelengths comprised between 350 nm and 800 nm.

The graphene layer in question in step (i) is advantageously a graphene monolayer produced by chemical vapor deposition (CVD) and the transmittance value of which is higher than 95%.

Many techniques of this type are available and the invention is not limited to one thereof. All of these techniques aim to form the graphene layer on a temporary growth substrate including a catalytic layer such as copper and platinum. The transfer of the graphene layer to a target subject, may thus be achieved, using a conventional wet transfer technique or by dry processing in particular such as detailed below.

The graphene layer in question in step (i) is advantageously carried by a substrate.

Generally, in the context of the present invention, the term “substrate” makes reference to a solid base structure on one of the faces of which at least one graphene layer is deposited.

The substrate may be of various natures.

It may be a question of a rigid or flexible substrate.

The substrate may be transparent, translucent, opaque or tinted. It may also be a question of a temporary substrate such as mentioned above.

However, in the case where the layer of graphene doped according to the invention is intended to be implemented in a device that is required to satisfy optical properties of transparency, for example for a touch screen or a viewing device, etc., this target substrate is advantageously formed from a transparent material.

This substrate may thus be a substrate made of glass or made of transparent polymers such as polycarbonate, polyolefins, polyethersulfone, polysulfone, phenolic resins, epoxy resins, polyester resins, polyimide resins, polyetherester resins, polyetheramide resins, polyvinyl acetate, cellulose nitrate, cellulose acetate, polystyrene, polyurethanes, polyacrylonitrile, polytetrafluoroethylene, polyacrylates such as polymethyl methacrylate, polyarylate, polyetherimides, polyether ketones, polyether ether ketones, polyvinylidene fluoride, polyesters such as polyethylene terephthalate or polyethylene naphthalate, polydimethylsiloxane, polyamides, zirconia, or derivatives thereof, or even silicon covered with a layer of nitride or a layer of oxide such as for example SiOₓ, or Al₂Oₓ.

According to a first variant, the graphene layer in question in step (i) is carried directly by a substrate.

Thus, according to one preferred embodiment, the graphene to be doped of step (i) of the process according to the invention is a graphene monolayer placed on the surface and directly in contact with a substrate made of a material chosen from glass, polyethylene terephthalate (PET), polycarbonate (PC), polyimide (PI), polyethylene naphthalate (PEN), polydimethylsiloxane (PDMS), polystyrene (PS), polyether sulfone (PES), silicon covered with a layer of oxide such as SiOₓ, Al₂Oₓ, etc., and preferably is chosen from glass and polyethylene terephthalate (PET).

According to another variant, the graphene layer in question in step (i) makes contact with a transparent undoped graphene layer that is inserted between said substrate and said graphene layer to be doped. In this embodiment, the graphene is a graphene bilayer and the doping concerns the external graphene layer.

According to yet another variant, the graphene layer in question in step (i) makes contact with a transparent doped graphene layer that is inserted between said substrate and said graphene layer to be doped.

Thus, according to this variant, the substrate is coated with a first layer of graphene with doping “GD”, itself coated with a layer of undoped graphene “G” and the architecture of which may be symbolized by “GDG”.

Advantageously, the first graphene layer with doping “GD” will have itself been able to be prepared beforehand by doping with a layer of graphene “G” according to the process of the invention.

More precisely, this type of “GDG” architecture stacked on a substrate may be obtained using the sequence of following reactions.

A first graphene monolayer carried by a substrate (named target substrate 1) is doped with a liquid solution of dopant in accordance with the process of the invention. This assembly consisting of the target substrate 1 and the doped first graphene layer may then form a target substrate (named target substrate 2) that is distinct from the target substrate 1.

A second graphene layer, which is identical to or different from the first layer, is then transferred, to the doped first layer carried by the target substrate 1 using a conventional wet-processing transfer process or, preferably, by dry processing in order to limit the loss of dopants during such a transfer.

Of course, it is possible to envision stacking, according to this technique, a plurality of layers of doped graphene “GD”, and/or undoped graphene “G”, these layers being inserted between the material from which the substrate is made and the graphene layer to be doped correspondingly for example to an architecture symbolized by “GDGDG” and representative of a contiguous stack of two layers of graphene with doping that is inserted between the substrate and the graphene layer to be doped.

It is important in contrast that the multilayer system thus formed possess the property of transmittance required according to the invention namely of at least 85% and in particular over all the spectrum in the visible.

The process according to the invention is therefore also useful for preparing a stack of layers of graphene doped with a dopant according to the invention.

### b) Liquid Solution of Dopants

As described above, the process according to the invention implements, by way of dopant, at least one salt or one organometallic complex of platinum or palladium of +IV or +II oxidation state.

As will become clear from the examples below, the inventors have observed that, completely unexpectedly, the dopants in question according to the invention are key to obtaining an improvement in the electrical conductivity of graphene that is temporally stabilized in terms of efficacy.

Without wanting to be tied by the theory, this gradual stabilization in the doping is realistically associated with a morphological and chemical reorganization of the dopant species on the surface of graphene.

Advantageously, the organometallic complexes or salts of platinum or palladium of +IV or +II oxidation state recommended for the invention lead to two-dimensional arrangements, that are potentially responsible for the stability effect. In contrast, salts of Au rearrange on the surface of the graphene to form 3-D metal particles of dimensions that may be micron-sized, thereby furthermore creating roughness that is disadvantageous for the manufacture of devices based on transparent electrodes (creation of short-circuits between the layers, etc.).

Advantageously and conversely to what is conventionally observed for other solutions of metal salts and in particular of Au, the doping remains active after temporal ageing of the sample. This effectiveness is in particular demonstrated in FIG. 4. A stabilized sheet resistance (R□∞) lower than the initial resistance before doping (R□ini) is preserved thereby. The organometallic complexes or salts of platinum or palladium of +IV or +II oxidization state recommended for the invention thus prove to be particularly advantageous comparatively to, for example, salts of Au. Specifically, they allow a doping efficacy that is stable over time to be ensured, in contrast to Au salts which gradually transform into gold metal and lead to a loss of the doping effect.

More particularly, by way of dopants according to the invention, mention may in particular be made of:
salts of platinum or palladium of formulae:

A₂MX₆,MX₄,A₂MX₄ and MX₂

in which:
A is a hydrogen atom, an NH₄ group, a sodium atom, a lithium atom or a potassium atom;
X is a fluorine atom, a chlorine atom, a bromine atom or an iodine atom; and
M is a platinum atom or a palladium atom of +IV or +II oxidation state.
   organometallic complexes of platinum or palladium such as for example Pt(CH₃)₃I; and
   mixtures thereof.

According to one preferred embodiment, the dopant is an organic metallic complex or salt of platinum or palladium of +IV or +II oxidation state of formulae such as defined above and is preferably the salt of PtCl_{4.}

As described above, the doping of the graphene layer using one or more dopants according to the invention is carried out by spraying a liquid solution conveying said dopant. In the present invention, this liquid solution may be interchangeably named “liquid solution of dopants” or “doping solution”.

For obvious reasons, the solvent medium composing the liquid doping solution is chosen suitably with regard to the nature of said dopant or dopants.

Most particularly recommended for the doping solution according to the invention are polar solvent media that allow inorganic dopants to be dissolved.

Mention may in particular be made of nitromethane, acetonitrile, acetone, methyl ethyl ketone, diethyl ether, tetrahydrofuran, dichloromethane, chloroform and other chlorine-containing solvents, benzonitrile, an alcohol-type solvent, in particular monoalcohols having from 1 to 5 carbon atoms.

According to one preferred embodiment, the solvent is nitromethane.

Moreover, solvents of higher boiling point such as N-methylpyrrolidone, N-ethylpyrrolidone, dimethylsulfoxide, ethylene glycol may be used and lead to a similar performance.

Thus, according to one particular embodiment, the liquid solution of dopant recommended for the invention may comprise a solvent chosen from nitromethane, acetonitrile, acetone, methyl ethyl ketone, diethyl ether, tetrahydrofuran, dichloromethane, chloroform and other chlorine-containing solvents, benzonitrile, an alcohol-type solvent, in particular monoalcohols having from 1 to 5 carbon atoms, N-methylpyrrolidone, N-ethylpyrrolidone, dimethylsulfoxide, ethylene glycol, and mixtures thereof, and preferably nitromethane.

According to one particularly preferred embodiment, the doping solution comprises PtCl₄ in solution in nitromethane.

Generally, the concentration of the doping solution recommended for the invention is lower than 5 mM and preferably varies from 0.1 mM to 3 mM in particular in the case where the dopant in question according to the invention is PtCl₄.

### c) Technique for Depositing by Spraying

As mentioned above, in a process according to the invention, the doping solution is brought into contact, in step (ii) with at least one zone or even the entire surface of the graphene layer to be doped, by spraying preferably through a nozzle.

Specifically, the inventors have observed that in contrast to other deposition techniques and in particular the technique for depositing by dipping, the use of a technique for depositing by spraying allows the quantity of dopants deposited on the surface of the graphene to be increased without physical limitation.

In other words, the combination of spraying by way of doping technique with the dopant chemical nature required according to the invention allows, after stabilization, a doping efficacy that is clearly better with respect to common techniques for depositing dopants to be achieved.

This result is in particular illustrated in FIG. 5 which shows that the technique for depositing PtCl₄ by manual spraying in accordance with the invention advantageously allows doped graphene to be obtained the sheet resistance of which after doping is much lower than that obtained for graphene doped with a dipping technique.

Moreover, the technique for depositing by spraying proves to be particularly effective in terms of yield (expressed by the ratio by weight of the quantity of dopants deposited on the surface of the graphene to the quantity of dopants in the initial doping solution), with respect to the other deposition techniques. Thus, in contrast to the techniques for depositing by dipping or spin-coating, a yield close to 100%, without loss of precious metal, is effectively possible, this being a definite economic advantage.

Preferably, the spraying according to the invention consists in nebulizing into a mist of fine droplets the liquid solution of dopant(s) over at least one zone or even the entire surface of the graphene layer to be doped.

The spraying may be carried out in manual or continuous mode.

According to a first variant, the dopants may be deposited on the surface of the graphene by automatic spraying. This spraying may be carried out by means of a nozzle subjected to ultrasonic vibrations, for example by means of a piece of industrial equipment sold by the company SONO-TEK.

According to a second variant, the dopants may be deposited on the surface of the graphene by manual spraying. This spraying may be carried out by means of a nozzle, in particular using a manual AZTEK airbrush, for example of 0.7 mm diameter.

The graphene layer intended to be doped is oriented to face the nozzle and generally placed at a controlled distance with respect to the outlet of the nozzle.

As detailed below, the nozzle may be stationary or mobile just like the entity made up of the substrate/graphene layer to be doped.

The embodiment in which the entity made up of the substrate/graphene layer to be doped remains stationary is in particular illustrated in FIG. 1 (a).

The embodiment in which the entity made up of the substrate/graphene layer to be doped is movable is illustrated in FIG. 1 (b). It is in particular representative of an on-the-fly doping technique using a roll-to-roll process.

In this variant embodiment, the movable nozzle used is advantageously a nozzle subjected to ultrasonic vibrations the frequency of which is increased proportionally to how small it is desired for the size of the droplets to be.

This movable nozzle may be moved in such a way, for example along a crossed path, that allows the uniformity of the deposition of dopants to be promoted. By performing a plurality of crossed passages, a plurality of consecutive depositions of dopants may thus be superposed on the same zone of the graphene layer to be doped in order to maximize the quantity of dopants on the surface of the graphene.

The duration of the spraying onto the treated zone or the entire surface of the graphene layer to be doped is therefore variable. As mentioned above, the use of various durations for the spraying allows, just as the use of solutions of dopants of various concentrations, the quantity of dopants which is deposited on the graphene layer to be doped to be adjusted.

According to one particular embodiment, the substrate carrying the graphene layer may be placed in immediate proximity or even make contact with a heating system such as a heated holder or a hot plate raised to a temperature suitable for removing the liquid medium conveying the one or more dopants according to the invention.

According to another particular embodiment, the liquid solution of dopant(s) may be sprayed through a mechanical mask, for example a stencil mask, so as to dope only one zone of the graphene layer to be treated.

The mask, which is inserted between the nozzle and the substrate, remains stationary and is placed slightly above the graphene layer to be doped in order not to damage it. There is no direct contact between the layer and the mask. After doping and (temporal or temperature) stabilization, the layer of doped graphene thus obtained includes undoped zones and doped zones defined according to the pattern of the mask. It follows that the doped zones are endowed with an electrical conductivity higher than that of the undoped graphene zones. The technique for depositing dopants by spraying through a mechanical mask thus allows dopants to be localized in defined zones on the surface of the graphene.

This controlled variability in dopant concentration over a graphene surface may also be advantageously adjusted via the control of the spraying onto the surface of the graphene layer through the mobility of the spraying nozzle and/or the assembly made up of the substrate/graphene layer.

According to one preferred embodiment, the assembly made up of the substrate/graphene layer remains stationary and the nozzle is movable.

According to another preferred embodiment, the nozzle remains stationary and the assembly made up of the substrate/graphene layer is movable and runs according to a roll-to-roll process. This process may be carried out via a thermal release tape (TRT) as described in the publication Bae et al., Nature Technology, 5, 2010, 574 or patent application US 2015/0162408 A1. Strips corresponding to various dopant densities may therefore thus be created. For a given run speed, the quantity of dopants which is deposited in the various zones depends on the dimensions of the apertures. A roll-to-roll type process allows distinct zones of electrical conductivity to be created by choosing various dopant densities or doping gradients as the assembly made up of the substrate/graphene layer runs past.

Advantageously, this embodiment allows doped zones and undoped zones to be alternated, or zones with various doping efficacies to be alternated.

### d) Adjustment of the Quantity of Dopants on the Graphene Layer Obtained According to the Invention

As specified above, the invention more particularly stems from the observation by the inventors that it proves to be possible, by virtue of the choice of the deposition technique and the nature of dopant, to obtain a layer of doped graphene with an excess of dopant and that this excess in dopants, proves to be key to accessing a doping efficacy that is advantageously stabilized during ageing of the doped graphene zone.

Unexpectedly, the doping with an excess of dopants allows the zone of the graphene layer treated to be endowed, indeed with a sheet-resistance value just after doping, R□D, that is significantly decreased with respect to the native sheet-resistance value R□ini but above all with a stabilized sheet-resistance value R□∞, which remains significantly lower than R□ini. This improvement in efficacy, which improvement is advantageously stabilized over time, is furthermore obtained for a good level of transmittance.

Thus, and as demonstrated in the examples that follow, the implementation of a deposition technique different from spraying, such as dipping is not suitable for obtaining this excess in dopant(s). During the dipping, the surface of the graphene layer is in equilibrium with the doping solution and its area cannot be arbitrarily increased. Specifically, the solubility of the doping reactant in the solvent is not infinite and the equilibrium between the solution and the surface of the graphene limits the absorbed quantity of dopants.

In contrast, the technique for depositing by spraying in question according to the invention allows excess doping with dopant Q which, against all expectation, is a pre-requirement for an effective sheet-resistance value R□∞.

Advantageously, the value of R□∞ decreases and approaches the value of the sheet resistance just after doping R□D, as the quantity of dopants in excess increases.

This effect is in particular illustrated in FIG. 3, which shows that the sheet resistance R□∞ of a graphene layer doped by automatic spraying of four successive layers of dopants with a 1 mM solution of PtCl₄ in nitromethane is 200 ohms/square versus 300 ohms/square for a graphene layer doped by manual spraying during 30 seconds with the same solution. The respective transmittances of 94.4% and 96.6%, measured at 550 nm just after doping under the two conditions, are evidence of a higher quantity of dopants under the 1^{st} doping condition.

More preferentially, the quantity of dopant is advantageously adjusted so as to obtain a stabilized sheet resistance in doped zones of the graphene layer lower than or equal to 350 ohm/square and a transmittance over all of the visible spectrum of at least 85%.

Likewise, the quantity of dopant is advantageously suitable for providing said doped graphene zone with a sheet resistance R□∞ the value of which corresponds to a decrease of at least 10%, preferably at least 30% or even at least 50% of the value of R□ini, while preserving a transmittance value higher than 85% over all of the visible spectrum.

The adjustment of the quantity Q of dopant may advantageously be controlled by measuring the transmittance of the zone of the graphene layer treated at a given wavelength, in particular at 550 nm as illustrated in FIG. 2b.

This transmittance at 550 nm may be measured by means of a UV-visible spectrophotometer. It is also possible to consider an on-line measurement by means of a visible laser (HeNe, diode laser) or a near-infrared laser.

Thus, according to one particular embodiment, the process according to the invention controls the adjustment of the quantity of dopants Q level with the zone of the graphene layer treated according to the invention by measuring the transmittance in the visible domain of the carbon layer of step (ii).

According to one preferred variant, this control is achieved by comparing said transmission measurement obtained at the end of the doping, preferably the same day as the doping or 1 to 2 days after, with a reference transmittance measurement obtained beforehand on the graphene layer of step (i).

This transmittance is inversely proportional to the quantity of dopants, as illustrated in FIG. 2b.

Thus, the present invention also targets the process variant comprising at least the steps consisting in:

(ia) measuring the value of the transmittance Tᵢₙᵢ of the graphene layer in question in step (i) preliminarily to the performance of step (ii);

(iia) measuring the value of the transmittance T_{D} of said doped graphene layer just after the doping step (ii); and

(iib) evaluating the quantity of dopants, and therefore in particular the efficacy of the doping, by comparing the transmittance T_{D} to the transmittance Tᵢₙᵢ, a value T_{D} lower than a value Tᵢₙᵢ being representative of effective doping.

Assuming no significant difference is observed between the values T_{D} and Tᵢₙᵢ, the doping of step (ii) is continued or reproduced with where appropriate an adjustment of the spraying conditions and/or of the concentration of dopants in the liquid solution of dopants.

Advantageously, the quantity of dopant and the deposition conditions may thus be adjusted and optimized on the basis of the value of the optical transmittance.

Advantageously, the process according to the invention furthermore comprises consecutively to the doping step (ii) a step (iii) aiming to stabilize the dopants on the graphene layer.

This step (iii) is a step of temporal stabilization, which may optionally be accelerated by thermal processing.

In this variant embodiment, the process according to the invention may advantageously comprise a step (iiia) consisting in measuring the value of the transmittance T_{∞} of said doped and stabilized graphene layer, and consecutively, a step (iiib) consisting in evaluating the efficacy of the doping by comparing the transmittance T_{∞} to the transmittance Tᵢₙᵢ, a value T_{∞} lower than a value Tᵢₙᵢ being representative of effective doping preserved after stabilization.

Advantageously, the process according to the invention may furthermore comprise consecutively to the doping step (ii), and if present the stabilization step (iii) such as defined above, at least one step (iv) consisting in transferring, by dry processing or by wet processing, a preferably transparent graphene layer to the surface of the layer of doped graphene which is obtained at the end of step (ii).

This second variant embodiment is a particularly advantageous alternative to the aforementioned temporal stabilization or stabilization by thermal processing. Specifically, a better electrical conductivity is observed for the corresponding doped graphene monolayer. This is mainly due to the preservation of the dopants by encapsulation with the transferred upper graphene layer.

Of course, this new graphene layer may in its turn be implemented in a process according to the invention, by way of the graphene layer to be doped in question in step (i).

### II—Layer of Doped Graphene Obtained According to the Invention and its Applications

As mentioned above, the graphene layer doped according to the process of the invention is characterized by a sheet-resistance value R□∞.

The sheet resistance R□∞ of the layer of graphene doped according to the invention is significantly lower than the sheet resistance of the undoped graphene zone, namely R□ini, in particular by at least 10%, preferably at least 30% or even at least 50% with respect to the value of R□ini.

The value of this stabilized sheet resistance R□∞ may be equal to the value of the resistance R□D. Generally, it is comprised between the values R□ini, and R□D.

A sheet resistance of a doped graphene layer in question according to the invention may be characterized as being in accordance with the stabilized sheet resistance R□∞ required according to the invention from the point at which no variation or increase of more than 8% of its value over time is observed.

Tests may where appropriate be implemented to characterize it. For example an “ageing” test over a duration possibly reaching as long as 50 days or even more or else less, at room temperature (20° C.+/−3° C.) and atmospheric pressure, counted from the doping. Another test, which is more rapid in terms of duration, may consist in applying an anneal at a temperature comprised between 100° C. and 200° C. just after doping of the layer of doped graphene. The alternative temperature stabilization allows accelerated “ageing” to be induced, in order to more rapidly achieve an R□ value that is stable over time and quantified by R□∞. Of course, this temperature depends on the salt used and on the quantity of dopants on the surface of the graphene. These measure adjustments are clearly within the ability of a person skilled in the art. Typically, this temperature is higher than or equal to the temperature used in the step of spraying the dopant and lower than 200° C.

According to another aspect, the present invention relates to a material comprising at least one layer of doped graphene obtained by the process such as defined above. Such a material possesses advantageous properties in terms of electrical conductivity and transparency.

Graphene doped via the process according to the invention may be used for many applications: flexible and ultra-thin screens, touchscreens, batteries, solar cells, electronics, optoelectronics, spintronics, biosensors, treatment of pollution, etc.

Furthermore, this doped graphene provides an advantageous alternative for the production of transparent conductive electrodes that are comprised in viewing devices (displays, flat screens, organic light-emitting diodes (OLED)) or photovoltaic devices.

Of course, the invention is not limited to the embodiments described above.

The invention will now be described by means of the following figures and examples, which are given by way of nonlimiting illustration of the invention.

### FIGURES

FIG. 1: Schematic illustration of a deposition by spraying on a stationary substrate (e) (static mode), or on a movable substrate (b) (dynamic mode) for an on-the-fly doping process of the roll-to-roll type.

FIG. 2: Compared efficacy of the doping of a graphene monolayer by means of a solution of PtCl₄ diluted in nitromethane to a concentration of 1 mM and produced by superposing one, two then four layers of dopants on the surface of the graphene.

FIG. 2a shows the sheet resistance R□D measured just after doping, as a function of the number of layers of dopants (namely one, two then four) for an increasing quantity of dopants Q, 2Q then 4Q, respectively.

FIG. 2b shows the associated transmittance values measured at 550 nm just after doping.

FIG. 3: Variation as a function of time of the sheet resistance R□∞ of a graphene monolayer after doping with a solution of PtCl₄ diluted in nitromethane (1 mM) for two different quantities of dopants (Q) (examples 1 and 2).

FIG. 4: Compared efficacy of the doping of a graphene monolayer by means of manual spraying for two different metal complexes, PtCl₄ according to the invention or HAuCl₄ not according to the invention.

FIG. 4a illustrates samples 2a and 2b of example 2, which samples were doped with PtCl₄ solutions with respective concentrations of 1 mM and 2.5 mM.

FIG. 4b illustrates samples 3a and 3b, which were doped with HAuCl₄ solutions with respective concentrations of 0.25 mM and 2.5 mM.

FIG. 5: Influence of the deposition technique on the variation as a function of time of the sheet resistance of a graphene monolayer after doping with a solution of PtCl₄ diluted in nitromethane (2.5 mM).

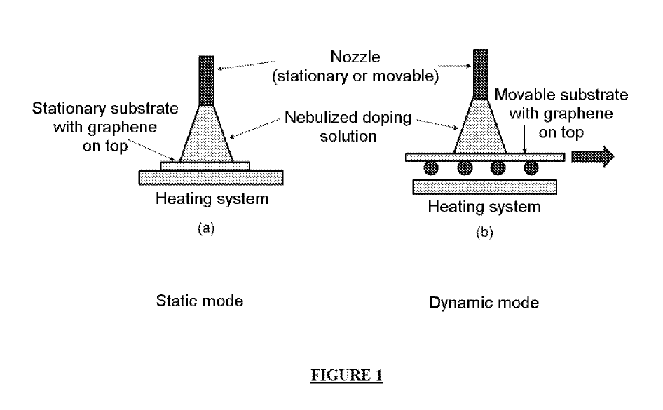

It should be noted that, for the sake of clarity, the various elements that may be seen in the figures are not drawn to scale, the actual dimensions of the various portions being different from shown.

### EXAMPLES

The following abbreviations have been used:
R□: Sheet resistance
R□ini: Initial sheet resistance, i.e. sheet resistance before doping
R□D: Sheet resistance D, i.e. sheet resistance just after doping
R□∞: Sheet resistance co, i.e. sheet resistance after doping and after stabilization
Ω/□: Ohm/square
T: Transmittance at 550 nm
Tini: Transmittance at 550 nm before doping, i.e. just after the transfer of the second graphene layer depending on the mentioned circumstances
T D: Transmittance at 550 nm just after doping
T∞: Transmittance at 550 nm measured after doping and stabilization
Smpl: Sample
G: Graphene monolayer
GD: Doped graphene monolayer
GDG: Doped graphene monolayer covered with a graphene monolayer
GDGDG: Doped graphene monolayer covered with a doped graphene monolayer itself coated with a graphene monolayer

Measuring Methods

The sheet resistance of the graphene layer is measured over all of the surface of the sample using a four-point Hall-effect measuring technique with a Van der Pauw geometry, using an Ecopia HMS-3000, for a current comprised between −100 and +100 μA

The transmittance, T, is measured at 550 nm by means of a UV-visible-near-infrared spectrophotometer of the Agilent-cary-5000 type. T is the ratio of the transmittances between the sample to be characterized and made up of a transparent substrate covered with one or more doped or undoped graphene monolayers and a reference sample corresponding to a bare substrate of identical nature.

### Example 1: Graphene Monolayer Doped by Means of SONO-TEK Automatic Spraying (Stationary Substrate and Movable Nozzle)

(i) Sample 1:

The substrate is a glass substrate the dimensions of which are 2.5×2.5 cm². The graphene is a graphene monolayer, produced by chemical vapor deposition (CVD) on a copper foil and transferred to the glass substrate using a conventional wet transfer technique conventionally described in the literature via a sacrificial polymethyl methacrylate (PMMA) carrier layer, wet etching of the copper, and collection, on the surface of the (glass) target substrate of the graphene/PMMA stack floating on the surface of the water rinse bath using the process described in the publication Suk et al., ACS Nano, 5, 2011, 6916.

(ii) Doping Solution:

The doping solution is formed of solid PtCl₄ salt dissolved in nitromethane. The concentration of the solution is 1 mM.

(iii) Deposition Conditions of the Dopants:

The dopants are deposited on the surface of the graphene by automatic spraying by means of a nozzle subjected to ultrasonic vibrations via a piece of industrial equipment sold by the company SONO-TEK. The nozzle placed above the substrate, at a distance of 10 cm, is moved above the sample to be doped, which remains stationary and is placed on a carrier heated to 110° C. The spray is created by the nozzle by means of an ultrasound system, at a frequency of 48 kHz. The solution is injected into the nozzle at the rate of 0.75 mL/min. The nozzle is moved above the sample so as to scan a path in steps of 5 mm, corresponding to a crossed passage, in order to promote the uniformity of the deposition. A plurality of “layers” of dopants (one, two then four layers) are superposed on the same sample in order to maximize the quantity of dopants (named Q, 2Q and 4Q, respectively) on the surface of the graphene, by performing a plurality of crossed passages over the same sample. For example, four “layers” of dopants correspond to four crossed passages of the nozzle.

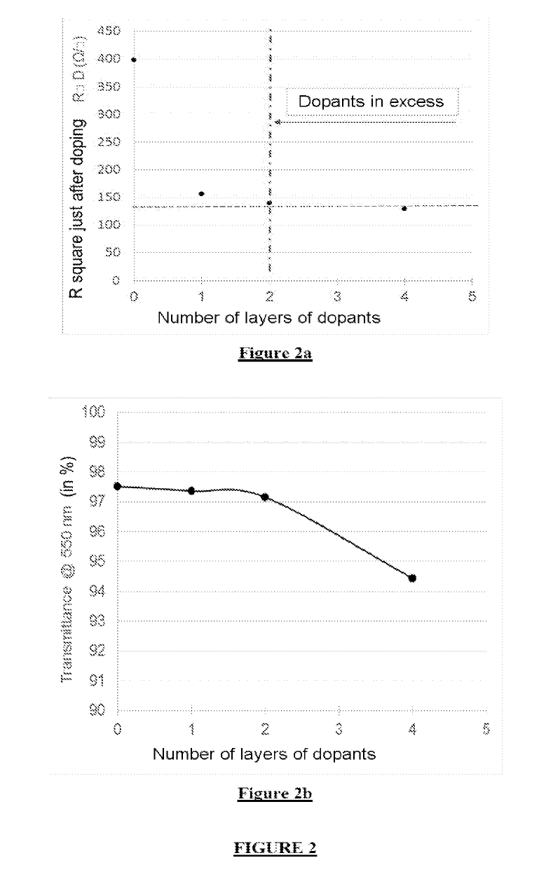

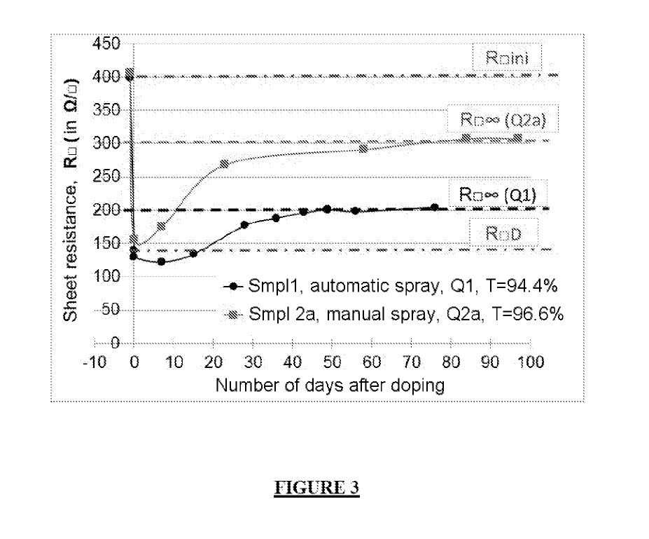

The electrical and optical performance of this sample before and after doping (just after doping and where appropriate after temporal stabilization) as a function of the number of crossed passages, namely one, two and four passages, of the nozzle above the sample are presented in tables 1a and 1b and in FIGS. 2a, 2b and 3.

TABLE 1a
Before doping

| | Transmittance |
|---|---|
| R□ini | at 550 nm, Tini |
| (in Ω/□) | (in %) |
| 398 | 97.5 |

TABLE 1b

| | Just after doping | | |
|---|---|---|---|
| Number of crossed | | Efficacy of the | |
| passages or of | | doping or decrease | |
| “layers” of | | in R□ (1 − R□D/ | Transmittance |
| dopants/Quantity | R□D | R□ini) × 100 | at 550 nm, T_{D} |
| of dopants | (in Ω/□) | (in %) | (in %) |
| 1/Q | 156 | 60.8 | 97.4 |
| 2/2Q | 140 | 64.8 | 97.2 |
| 4/4Q | 129 | 67.6 | 94.4 |

The results show that the superposition of four “layers” of dopants satisfies the notion of dopants in “excess”: specifically, this condition does not induce a significant decrease in R□D with respect to the superposition of 2 layers of dopants. In addition, this quantity of dopants proves to be compatible with a satisfactory transmittance value (value of 94.4%).

An ageing test, was furthermore carried out on the doped carbon-containing layer having undergone 4 successive sprays.

This ageing test consists in keeping, just after doping, the doped sample for more than 60 days at room temperature (20° C.+/−3° C.) and atmospheric pressure

After temporal stabilization, R□∞ possesses a value of about 200Ω/□, this corresponding to a decrease of 50% in the sheet resistance before doping R□ini and therefore to a significant improvement in conductivity.

### Example 2: Graphene Monolayer Doped by Means of Manual Spraying (Stationary Substrate and Nozzle)

(i) Samples 2a and 2b:

The samples are identical to that prepared in example 1.

(ii) Doping Solutions:

Two doping solutions the concentration of which in solid PtCl₄ salt dissolved in nitromethane is 1 mM and 2.5 mM, respectively, are prepared.

(iii) Deposition Conditions of the Dopants:

Each of the solutions is nebulized via a nozzle using an AZTEK manual airbrush, of 0.7 mm diameter. It remains stationary, and is held above the sample at a distance of 20 cm. The substrate remains stationary, centered perpendicular to the outlet of the nozzle and is placed on a hot plate at 110° C.

(iv) Duration of the Exposure to the Nebulization:
The sample 2a is exposed for 30 seconds to the solution of dopants the concentration of which is 1 mM.
The sample 2b is exposed for 15 seconds to the solution of dopants the concentration of which is 2.5 mM.

The use of solutions of different concentrations and the use of different durations of exposure to the nebulization allows the quantity of dopants which is deposited on the surface of the graphene to be varied.

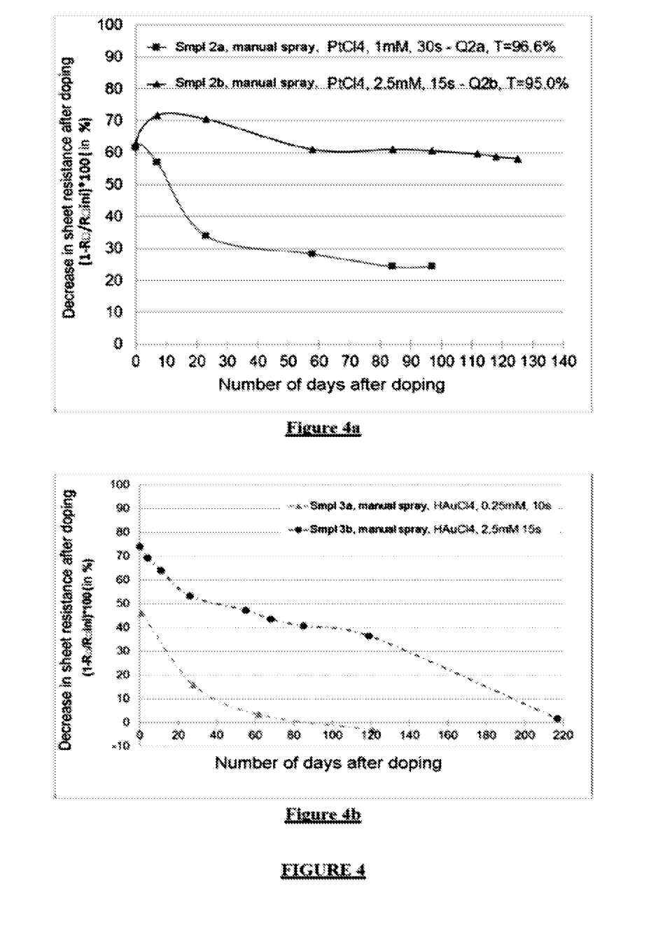

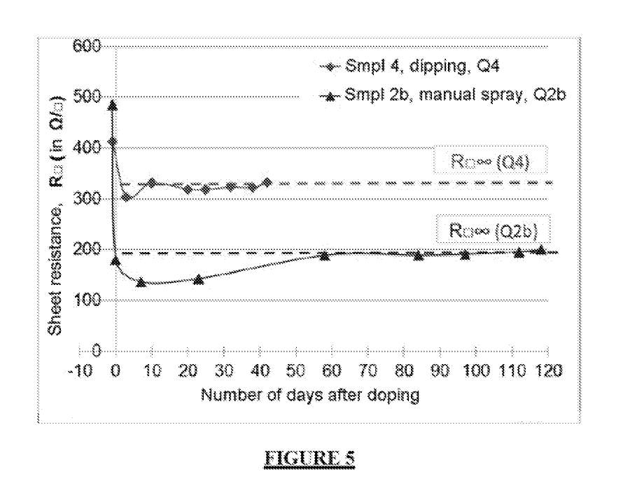

The electrical and optical performance of the samples 2a and 2b, before and after doping (just after doping and after temporal stabilization of more than 60 days, are presented in tables 2a and 2b and in FIGS. 3 and 4a.

TABLE 2a

Before doping

| | | Transmittance |
|---|---|---|
| | R□ini | at 550 nm, Tini |
| | (in Ω/□) | (in %) |
| Smpl 2a | 406 | 97.3 |
| Smpl 2b | 485 | 97.4 |

TABLE 2b

| | | | | After temporal | |
|---|---|---|---|---|---|
| | Just after doping | | | stabilization | |
| | | Efficacy of the | | | Efficacy of the |
| | | doping | | | doping |
| | | (1 − R□D/ | Transmittance | | (1 − R□∞/ |
| Doping | R□D | R□ini) × 100 | at 550 nm, T_{D} | R□∞ | R□ini) × 100 |
| conditions | (in Ω/□) | (in %) | (in %) | (in Ω/□) | (in %) |
| Smpl 2a: | 156 | 61.6 | 96.6 | 300 | 26 |
| PtCl₄, 1 mM, | | | | | |
| 30 s | | | | | |
| Smpl 2b: | 181 | 62.3 | 95.0 | 195 | 60 |
| PtCl₄, 2.5 mM, | | | | | |
| 15 s | | | | | |

The use of the PtCl₄ doping solution of highest concentration, namely 2.5 mM allows an R□∞ value of about 195Ω/□ to be obtained after temporal stabilization, versus a value of 300 for the R□∞ value obtained with the sample 1 doped with a lesser quantity of PtCl₄, as evidenced by the respective transmittance values measured just after doping.

It will be noted that in contrast the R□D of the two samples are comparable.

These results therefore indeed reveal the beneficial effect of the presence of an excess of dopants on the R□∞ of a layer of graphene thus doped. The efficacy of the doping is furthermore not obtained to the detriment of the transmittance which remains satisfactory since of 95%.

### Example 3: Production of a Graphene Bilayer with Insertion of the Dopants (Graphene/Dopants/Graphene: GDG), after Stabilization of the Dopants of the First Layer and Transfer of the Second Layer Using a Dry Process

A first graphene layer produced on a copper foil then transferred to a glass substrate is doped with a PtCl₄ solution according to example 1 and more particularly according to the modalities of sample 1.

The dopants are stabilized either after a minimum duration of about 60 days (temporal stabilization), or after annealing of the sample just after doping at 100° C. for 1 h under vacuum and waiting a minimum duration of 30 days (temperature-accelerated stabilization). The step of transferring the second graphene layer after the stabilization of the dopants is carried out this time using a dry process, such as those conventionally described in the literature according to for example the publication Suk et al., ACS Nano, 5, 2011, 6916.

The transfer is performed via a sacrificial carrier polymer placed or deposited on the surface of the graphene and the etching of the copper is performed in solution. In contrast, the transfer of the stack made up of the graphene/polymer carrier to the target substrate (glass substrate with the doped first graphene layer) is performed by dry processing. using a layer of PMMA covered in a polydimethylsiloxane (PDMS) frame as described in the publication Suk et al., ACS Nano, 5, 2011, 6916.

Table 3 collates an example of the electrical and optical performance of the layers during the various steps of this example.

TABLE 3

| | | | R□(∞) | | Transmittance |
|---|---|---|---|---|---|
| | | | After | | at 550 nm |
| | | | temporal | Transmittance | after temporal |
| | | R□ | stabilization | at 550 nm | stabilization |
| Graphene | Smpl 1: G | R□ini(1) = 398 Ω/□ | | Tini(1) = 97.5% | Not measured |
| monolayer | Before | | | | |
| | doping | | | | |
| | GD | R□D = 129 Ω/□ | R□∞ = 200 Ω/□ | T_{D} = 94.4% | T∞ = 95.6% |
| | Doping: | | | | |
| | automatic | | | | |
| | spraying, | | | | |
| | PtCl₄ | | | | |
| | 1 mM, 4 | | | | |
| | layers of | | | | |
| | dopants | | | | |
| Bilayer | GDG | R□ini(2) = 136 Ω/□ | | Tini(2) = 93.2% | Not measured |
| system | After | | | | |
| | transfer | | | | |
| | of the 2^{nd} | | | | |
| | graphene | | | | |
| | layer | | | | |

It will be noted that the bilayer stack GDG of graphene with insertion of the dopants allows a transmittance of 93.2% and an R□ of 136Ω/□ to be achieved comparatively to the corresponding doped and stabilized graphene monolayer, GD, which allows a transmittance of 95.6% and an R□ of 200Ω/□ to be accessed. The decrease in transmittance and sheet resistance observed after addition of the upper graphene layer are consistent with the preservation of the dopants during the step of transferring the 2^{nd} layer.

The addition of the 2^{nd} graphene layer allows the electrical conductivity of the stack to be further improved, with respect to a stabilized and doped graphene monolayer, while preserving an acceptable transmittance.

### Example 4: Efficacy of the Doping, Comparison Between Solutions of PtCl₄ in Nitromethane Appropriate for the Invention and Solutions of HAuCl₄ in Nitromethane not According to the Invention

FIGS. 4a and 4b compare the variation as a function of time of the efficacy of doping by manual spraying achieved respectively by means of
a) complexes appropriate for the invention (doping with solutions of PtCl₄ in nitromethane for respective concentrations of 1 mM and 2.5 mM, see example 2) and
b) Au salts not according to the invention (doping with solutions of HAuCl₄ in nitromethane for respective concentrations of 0.25 mM and 2.5 mM, and respective durations of 10 seconds and 15 seconds).

The efficacy of the doping may be expressed via a percentage representative of the decrease in the sheet resistance induced by the doping with respect to the value of the sheet resistance before doping: (1−R□/R□ini)×100.

From examination of FIGS. 4a and 4b, it will be clear that:

With the Au salts as illustrated in FIG. 4b, depending on the deposition conditions, the dopants are gradually lost over time. In the end, after a characteristic time (typically comprised between 90 and 220 days), the sheet resistance of the graphene returns to a value equal to or even higher than the undoped initial value. In other words, the doping efficacy is zero.

The nature of the dopant used and its oxidation state on the surface of the graphene may be analyzed by x-ray photoelectron spectroscopy (XPS).

For doping according to the invention, after temporal ageing of the doped sample, the preservation of species in the +IV or +II oxidation state, not entirely converted into metal (oxidation state 0), is representative of the preservation of the charge-transfer doping effect over time.

In contrast, an Au salt on the surface of the graphene gradually converts at room temperature into gold metal, this possibly being associated with the total loss of the doping effect.

1. A process that is useful for preparing a graphene layer that is transparent and of stabilized and improved electrical conductivity, said process comprising at least the steps of:
(i) providing at least one graphene layer that is transparent and that possesses a sheet resistance, R□ini,
(ii) doping at least one zone of said graphene layer to form a doped graphene zone having a stabilized sheet resistance, R□∞, of value lower than R□ini,
wherein step (ii) is carried out by spraying the surface of at least said zone of said graphene layer (i) with at least one dopant chosen from organometallic complexes and salts of platinum or palladium of +IV or +II oxidation state.

2. The process according to claim 1, wherein the value of the stabilized sheet resistance, R□∞, is comprised between the value R□ini and the sheet-resistance value obtained just after doping R□D.

3. The process according to claim 1, wherein the graphene layer to be doped possesses a transmittance value higher than or equal to 85%.

4. The process according to claim 1, wherein the graphene layer is a graphene monolayer produced by a chemical-vapor-deposition (CVD) technique and the transmittance value of which is higher than 95%.

5. The process according to claim 1, wherein the graphene layer of step (i) is carried by a substrate.

6. The process according to claim 5, wherein the substrate is transparent or translucent in the visible or infrared domain and chosen from glass, polyethylene terephthalate, polycarbonate, polyimide, polyethylene naphthalate, polydimethylsiloxane, polystyrene, polyethersulfone, silicon covered with a layer of nitride or with a layer of oxide such as SiOₓ, or Al₂Oₓ, and preferably is chosen from glass and polyethylene terephthalate.

7. The process according to claim 5, wherein said graphene layer of step (i) makes direct contact with said substrate.

8. The process according to claim 5, wherein said graphene layer makes contact with a doped graphene layer that is inserted between said substrate and said graphene layer to be doped.

9. The process according to claim 8, wherein said doped graphene layer placed in contact with the graphene layer itself has been obtained by doping a graphene layer using the process of steps (i) and (ii).

10. The process according to claim 1, wherein the dopant is chosen from:
salts of platinum or palladium of formulae:
A₂MX₆,MX₄,A₂MX₄ and MX₂
in which:
A is a hydrogen atom, an NH₄ group, a sodium atom, a lithium atom or a potassium atom;
X is a fluorine atom, a chlorine atom, a bromine atom or an iodine atom; and
M is a platinum atom or a palladium atom of +IV or +II oxidation state.

11. The process according to claim 1, wherein the dopant is chosen from the salts of PtCl₄, H₂PtCl₆, PtCl₂, H₂PdCl₆, PdCl₂, and mixtures thereof.

12. The process as claimed in claim 11, wherein the liquid solution of dopant is a PtCl₄ solution with a concentration lower than 5 mM and preferably varies from 0.1 mM to 3 mM.

13. The process according to claim 1, wherein the dopant is an organometallic complexes of platinum or palladium of +II or +IV oxidation state.

14. The process according to claim 1, wherein the dopant is Pt(CH₃)₃I.

15. The process according to claim 1, wherein the operation of spraying onto said graphene layer may be carried out in one go or repeated one or more times.

16. The process according to claim 1, wherein the step (ii) is carried out in dynamic mode using an on-the-fly doping technique and in particular a roll-to-roll technique.

17. The process according to claim 5, wherein the substrate carrying the graphene layer treated in step (ii) is heated to a temperature convenient for the removal of the solvent medium of the liquid solution of dopant.

18. The process according to claim 1 comprising the additional steps:
(ia) measuring the value of the transmittance Tᵢₙᵢ of the graphene layer in question in step (i) preliminarily to the performance of step (ii);
(iia) measuring the value of the transmittance T_{D} of said doped graphene layer just after the doping step (ii); and
(iib) evaluating the quantity of dopants by comparing the transmittance T_{D} to the transmittance Tᵢₙᵢ, a value T_{D} lower than a value Tᵢₙᵢ being representative of effective doping.

19. The process according to claim 1, furthermore comprising, consecutively to the doping step (ii), and if present step (iib), a step (iii) of stabilizing the organometallic complexes or salts of platinum or palladium of +IV or +II oxidation state in the doped graphene layer.

20. The process according to claim 1, furthermore comprising, consecutively to the doping step (ii) and if present stabilization step (iii), at least one step (iv) transferring, an undoped graphene layer to the surface of the layer of doped graphene which is obtained at the end of step (ii).

21. The process according to claim 1, wherein the dopant is PtCl₄, and the zone of the doped and stabilized graphene layer possesses, a stabilized sheet resistance, R□∞ lower than or equal to 350Ω/□ and a transmittance T higher than 85% over all of the visible spectrum.

22. A material comprising at least one layer of doped graphene obtained by the process such as defined in claim 1.

23. Method for manufacturing flexible and ultra-thin screens, touchscreens, batteries, solar cells, biosensors, electronic or optoelectronic devices, spintronics devices, transparent conductive electrodes intended to be incorporated into viewing devices such as displays, display screens, flat screens, and organic light-emitting diodes (OLED) or photovoltaic devices comprising a step of the process according to claim 1.

24. A device comprising doped graphene obtained by the process such as defined in claim 1.

25. The device according to claim 24, chosen from flexible and ultra-thin screens, touchscreens, batteries, solar cells, biosensors, electronic or optoelectronic devices, spintronics devices, transparent conductive electrodes, viewing devices such as displays, display screens, flat screens, and organic light-emitting diodes (OLED), and photovoltaic devices.
